(19) United States
(12) Patent Application Publication
(10) Pub. No.: US 2004/0231590 A1
(43) Pub. Date: Nov. 25, 2004

(54) Deposition apparatus for the formation of polycrystalline materials on mobile substrates

(76) Inventor: Stanford R. Ovshinsky, Bloomfield Hills, MI (US)

Correspondence Address: ENERGY CONVERSION DEVICES, INC., 2956 WATERVIEW DRIVE, ROCHESTER HILLS, MI, 48309, US

(21) Appl. No.: 10/440,664

(22) Filed: May 19, 2003

(51) Int. Cl. C23C 16/00

(52) U.S. Cl. 118/718

(57) ABSTRACT

A deposition apparatus and method for continuously depositing a polycrystalline material such as polysilicon or polycrystalline SiGe layer on a mobile discrete or continuous web substrate. The apparatus includes a pay-out unit for dispensing a discrete or continuous web substrate and a deposition unit that receives the discrete or continuous web substrate and deposits a series of one or more thin film layers thereon in a series of one or more deposition or processing chambers. In a preferred embodiment, polysilicon is formed by first depositing a layer of amorphous or microcrystalline silicon using PECVD and transforming said layer to polysilicon through heating or annealing with one or more lasers, lamps, furnaces or other heat sources. Laser annealing utilizing a pulsed excimer is a preferred embodiment. By controlling the processing temperature, temperature distribution within a layer of amorphous or microcrystalline silicon etc., the instant deposition apparatus affords control over the grain size of polysilicon. Passivation of polysilicon occur through treatment with a hydrogen plasma. Layers of polycrystalline SiGe may similarly be formed. The instant deposition apparatus provides for the continuous deposition of electronic devices and structures that include a layer of a polycrystalline material such as polysilicon and/or polycrystalline SiGe. Representative devices include photovoltaic devices and thin film transistors. The instant deposition apparatus also provides for the continuous deposition of chalcogenide switching or memory materials alone or in combination with other metal, insulating, and/or semiconducting layers.

### FIELD OF INVENTION

This invention relates to the continuous deposition of a polycrystalline material. More particularly, this invention pertains to an apparatus for depositing polysilicon and polycrystalline SiGe on mobile discrete or continuous web substrates. Most particularly, this invention relates to the continuous deposition of amorphous or microcrystalline silicon or SiGe and its transformation to polysilicon or polycrystalline SiGe in a continuous process.

### BACKGROUND OF THE INVENTION

Consumer and industrial interest in display technologies continues to grow as displays become more powerful and compact. New applications for displays continue to be developed and are guided by new concepts in materials, devices and configurations for displays. Important objectives for most display technologies include providing a resolution (low, medium or high) suitable for a particular application, providing sufficient brightness, minimizing power consumption, providing stable output, providing long lifetime, minimizing cost, and providing functionality in diverse operating environments. The industries and applications impacted by display technologies are too numerous to identify, but broadly include consumer electronics, automotive, computers, television and movies, billboards and other signage, cell phones, apparel etc.

An important display technology currently available and undergoing further development is active matrix liquid crystal displays. A liquid crystal display uses a liquid crystal material as the active material. In a liquid crystal display panel, light generated from the backside of the panel interacts with a liquid crystal material and is transmitted through the front side of the panel to a viewer. The liquid crystal material is present in a liquid crystal layer of a device structure and is typically sandwiched between two glass plates (a TFT (thin film transistor) glass plate and a color filter glass plate). The two glass plates are typically further sandwiched between two polarizing filters. The backlighting is transmitted, in order, through a bottom (backside) polarizer, the TFT glass plate, the liquid crystal layer, the color filter glass plate having a color filter layer present thereon, and a top (frontside) polarizer plate.

The transmission efficiency of the backlighting through the display depends on its polarization relative to the polarization of the top polarizer. The top polarizer completely transmits certain polarizations of light to provide bright spots, completely blocks other polarizations of light to provide dark spots, and partially transmits still other polarizations of light to provide spots of variable illumination intensity. The state of polarization of the backlighting that reaches the top polarizer is determined by the bottom polarizer (which establishes an initial polarization of the backlighting) and the state of the liquid crystal material, which modifies the initial polarization through interactions of liquid crystal molecules with the propagating backlighting. The influence of liquid crystal molecules on the polarization of the backlighting depends on the orientation, alignment and/or positioning of liquid crystal molecules in the liquid crystal layer. The state of the liquid crystal material, in turn, depends on the voltage applied to the liquid crystal layer across the surrounding TFT and color filter glass plates. The voltage applied across the liquid crystal layer induces motion, realignment or reorientation of liquid crystal molecules and this motion, realignment or reorientation influences the interaction of the liquid crystal molecules with the propagating backlighting, thereby altering the polarization thereof. The applied voltage thus provides a mechanism for altering the transmission efficiency of backlighting through a liquid crystal display by modifying the polarization of light as it propagates through the liquid crystal layer.

Most current liquid crystal display panels are divided into pixels, where each pixel includes an individually addressable portion of liquid crystal material. Addressing is most commonly accomplished with a multiplex driving method in which pixels are arranged and wired in a matrix format using a series of horizontal and vertical addressing electrodes. Individual pixels are driven by providing voltages at the intersections of specific vertical and horizontal electrodes. In an active matrix liquid crystal panel, a switching device and a storage capacitor are integrated at each electrode cross point. The active matrix configuration improves the contrast ratio and avoids the crosstalk problems found in simpler passive matrix designs, but requires a more complex fabrication scheme and supporting circuits to drive the switching devices. The most common switching devices are TFT transistors made from amorphous silicon (a-Si) because a-Si can be deposited over large area substrates (e.g. glass plates) at relatively low temperatures (300-400° C.). a-Si, however, is not an optimum switching device material because it has poor structural stability upon exposure to light over time and because it possesses a low charge carrier mobility. Although adequate for the purposes of switching individual pixels on and off, the low mobility of a-Si renders it unsuitable for performing the logic and mixed signal functions necessary to drive the display. As a result, external driver circuits based on transistors made from crystalline silicon (c-Si) are needed to drive the a-Si TFTs in liquid crystal displays. The need for external driver circuits further complicates the fabrication of liquid crystal displays, increases the overall device footprint, and increases power consumption.

The search for better switching devices has focused on the use of polycrystalline silicon (polysilicon, polySi or p-Si) because of its high charge carrier mobility. Polycrystalline silicon is a form of silicon that constitutes an aggregate of silicon crystallites (grains) having dimensions on the scale of a few hundred angstroms up to several microns. The higher mobility of polysilicon is a consequence of the high mobility of the crystalline phase of silicon relative to the amorphous phase of silicon. The high mobility of polysilicon means that switching devices (transistors) made from polysilicon can be much smaller in size than switching devices made from a-Si. As a result, the pixel size of liquid crystal displays can be decreased and higher resolution displays can be obtained. Since switching devices block the transmission of backlighting through a display, smaller switching devices lead to higher light throughput and higher display aperture ratios. Furthermore, since the mobility of polysilicon approaches that of c-Si, transistors made from polysilicon have the capacity to perform the logic and mixed-signal functions completed by the external c-Si driving circuits used in current active matrix liquid crystal display technologies. (Doped polysilicon devices (n-type and p-type) and CMOS circuits based on polysilicon can also be fabricated.) Consequently, the necessary driving circuits can be directly integrated with the switching devices on-board when polysilicon is used as the transistor material for the TFT switching devices.

In spite of the advantageous material properties of polysilicon, its use in active matrix liquid crystal displays (and active matrix organic light emitting diode displays, a display technology that would also benefit from polysilicon switching devices) has been limited because polysilicon is a more difficult material to deposit than a-Si. The properties of polysilicon-depend on grain size, defect concentrations, crystal uniformity etc. and deposition methods necessarily must strive to optimize each of these properties.

The capacity for scale-up to high manufacturing volumes is an important factor in determining the commercial cost effectiveness of a display technology. Of greatest interest from a cost standpoint are display fabrication methods based on continuous manufacturing processes. In a continuous process, arrays of multilayer device structures are formed in a deposition apparatus having a plurality of deposition chambers through a sequential deposition of individual layers on a flexible, continuous web substrate. Continuous manufacturing processes can be used to deposit insulating, semiconducting (including n-type, p-type and intrinsic) and metallic materials through methods such as chemical vapor deposition, plasma enhanced chemical vapor deposition, physical vapor deposition and sputtering to form a variety of device structures. Methods suitable for deposition over large area substrates are also of interest from the point of view of cost and for applications in which large, monolithic displays are desired.

Cost effective manufacture is one advantage of a-Si. a-Si can be deposited over large areas and a-Si deposition has been adapted to continuous deposition processes (e.g. solar cell deposition processes). It is desirable to develop a continuous deposition process for forming polysilicon. A continuous polysilicon process would advance the art of active matrix liquid crystal and organic light emitting diode displays by providing a cost effective route to an improved switching material.

### SUMMARY OF THE INVENTION

The instant invention provides a continuous deposition process and apparatus for polycrystalline materials such as polysilicon and polycrystalline SiGe. Deposition occurs on a continuously mobile substrate that is transported through a deposition apparatus that includes one or more deposition chambers for forming multi-layer device structures where at least one of the deposition chambers provides a polycrystalline layer. Deposition chambers that deposit thin film layers according to a variety of deposition methods may be included in the instant deposition apparatus. Typically, each deposition chamber is configured to provide a layer of material according to a particular deposition technique and the conditions within a chamber are adjusted to obtain thin film materials of a particular composition and thickness at a desired growth rate. Sequential and continuous transport of a mobile substrate through a plurality of deposition chambers leads to layer-by-layer deposition of materials having different compositions and/or thicknesses to provide a variety of device structures. Layer integrity is maintained by isolating the different deposition chambers from each other and by operating the deposition chambers independently of each other. Mobile substrates include continuous web substrates as well as discrete substrates that are conveyed through the deposition apparatus.

The instant deposition apparatus may include processing chambers in addition to deposition chambers or deposition chambers that also include processing means for modifying the structure, coverage, shape, phase or other characteristics of deposited materials.

Substrates in accordance with the instant deposition method and apparatus include stainless steel substrates, plastic substrates, and plastic coated steel substrates. Plastic (directly or through post-deposition etching of steel in a plastic coated steel substrate) provides a flexible substrate material for polysilicon and polycrystalline SiGe devices.

In one embodiment, the deposition apparatus includes a chamber for depositing amorphous or microcrystalline silicon and means for transforming amorphous silicon to polysilicon. Amorphous or microcrystalline silicon may be deposited by a technique such as chemical vapor deposition or plasma enhanced chemical vapor deposition. Transformation of amorphous or microcrystalline silicon to polysilicon may occur through a thermal annealing process such as furnace heating, lamp heating, rapid thermal processing or laser annealing where the transformation may be effected in the deposition chamber after deposition or in a separate processing chamber. Transformation of amorphous or microcrystalline silicon to polysilicon may occur over broad areas of a mobile substrate or selected portions thereof. In a preferred embodiment, polysilicon is formed through laser annealing using an excimer laser or lamp heating using Xe lamps. Polycrystalline SiGe may be similarly formed.

In another embodiment, the instant invention provides for the continuous deposition of polysilicon and/or polycrystalline SiGe and subsequent patterning thereof in a continuous process. Patterning steps include masking, photolithography, and inkjet printing.

In yet another embodiment, the instant invention provides for the deposition of thin film photovoltaic devices, transistors and other electronic devices that include a polysilicon and/or polycrystalline SiGe layer. The device and transistor structures may include metal layers, insulating layers and other semiconducting layers in addition to a polysilicon or polycrystalline SiGe layer. These layers may be provided in deposition chambers using deposition techniques that include one or more of chemical vapor deposition, plasma enhanced chemical vapor deposition, physical vapor deposition, or sputtering.

### BRIEF DESCRIPTION OF THE DRAWINGS

FIG. 1. A representative photovoltaic device structure that can be formed using the instant deposition apparatus.

FIG. 2. A representative thin film transistor that can be formed using the instant deposition apparatus.

### DETAILED DESCRIPTION OF THE INVENTION

The instant invention provides a process and apparatus for the deposition of a polycrystalline material in a continuous manufacturing process. The instant invention addresses the need for high volume deposition of polycrystalline materials and devices including same for display and other applications. In a preferred embodiment, the polycrystalline material is polysilicon or polycrystalline SiGe. The instant deposition apparatus includes one or more deposition chambers for depositing one or more layers on a continuously mobile substrate where at least one of the deposited layers is polysilicon or polycrystalline SiGe or where at least one of the deposited layers is amorphous or microcrystalline silicon or SiGe and where the amorphous or microcrystalline silicon or SiGe is transformed into polysilicon or polycrystalline SiGe in a deposition chamber or processing chamber of the apparatus. Single layer polysilicon depositions or multilayer structures that include a polysilicon and/or polycrystalline SiGe layer are within the scope of the instant invention.

In one embodiment, the instant deposition apparatus includes a pay-out unit for providing a continuously mobile substrate, a deposition unit in which one or more thin films is deposited on the continuously mobile substrate in one or more deposition chambers utilizing one or more deposition techniques, and a take-up unit for receiving the continuously mobile substrate after deposition. A pay-out unit generally provides a substrate feed to the instant deposition unit and may provide a fresh substrate or a substrate that has been treated, handled, or otherwise manipulated or modified by a process unit that precedes the instant deposition unit. Similarly, a take-up unit generally receives a mobile substrate that has passed through the instant deposition unit. A take-up unit may simply receive and store a mobile substrate or may redirect the substrate to other process units independent of the instant deposition unit for further processing, modification, packaging etc. In some embodiments, the instant deposition apparatus further includes one or more processing chambers for modifying the shape, structure or phase of a deposited layer. Means for processing may also be included integrally within a deposition chamber.

The deposition unit comprises one or a series of operatively connected deposition chambers wherein the conditions of each deposition chamber are established for the purpose of continuously depositing a thin film layer with an intended composition and thickness for a given substrate transport speed. Deposition chambers utilizing different deposition techniques may also be included in the instant deposition unit. By continuously transporting a mobile substrate through a series of chambers, multilayer structures comprising a layer of polysilicon or another polycrystalline material and, optionally, one or more additional layers of variable composition and thickness may be formed on a continuously mobile substrate.

Discrete or continuous web mobile substrates may be used in the instant apparatus. A continuous web substrate is a substrate having an extended length in the direction of transport within the deposition apparatus and may hereinafter be referred to as a “continuous web”, “web”, “continuous web substrate”, “web substrate” or the like. In a preferred embodiment, a continuous web extends at least a distance in one dimension corresponding to the distance between the pay-out and take-up units of the instant apparatus. In a particularly preferred embodiment, the length of a continuous web is substantially longer than the distance between the pay-out and take-up units. In a preferred embodiment, a continuous web substrate is a flexible material that can be rolled up and stored in the form of a roll in the pay-out and take-up units. Transport of a continuous web may occur by unspooling or dispensing the roll at the pay-out unit to provide a flat substrate that is transported through the deposition apparatus and respooling at the take-up unit to form a product roll having one or more layers deposited thereon.

A discrete mobile substrate is a mobile substrate that is not continuous, but rather in piece form. A discrete mobile substrate may be obtained, for example, by sub-dividing a continuous web substrate along its longest dimensions into a series of several pieces. A discrete mobile substrate may be desirable for applications where, for example, monolithic panels or signs of a certain size or shape are required. Display panels that are sized to meet the needs of, for example, cell phones or laptop computers may be formed on discrete mobile substrates in the instant deposition apparatus. Discrete mobile substrates include monolithic sheets, plates, wafers etc. of various sizes and shapes. In one embodiment, the dimensions of a discrete substrate are such that the substrate fits in its entirety within a deposition chamber of the instant apparatus. In another embodiment, the dimensions of a discrete substrate are such that a plurality of discrete substrates fit in their entirety within a deposition chamber of the instant apparatus. In still another embodiment, the dimensions of a discrete substrate are such that the length of the substrate in one direction exceeds the length of a deposition chamber in the same direction. In the instant deposition apparatus, discrete mobile substrates are continuously transported or conveyed through the deposition and processing chambers. Discrete mobile substrates may be attached to or positioned on, for example, a continuous band or surface that is continuously in motion (e.g. a conveyor belt). A plurality of discrete substrates may be introduced in such a way that each substrate within the plurality is independently introduced into the instant apparatus or in such a way that one or more substrates within the plurality are jointly introduced into the instant apparatus. In a preferred embodiment, a plurality of discrete mobile substrates are spatially separated and sequentially and continuously transported from a pay-out unit through the deposition apparatus to a take-up unit. Discrete sheets, for example, may be stored in a pay-out unit by stacking and individually distributed to a transporting device such as a continuous band or conveyor belt for transport and deposition and ultimately collected and re-stacked in a take-out unit. Various manners of introducing discrete substrates have been contemplated in U.S. Pat. No. 4,423,701 of the instant assignee, the disclosure of which is hereby incorporated by reference. Various ways of introducing a plurality of discrete or continuous substrates in a parallel manner have been discussed in pending U.S. patent application Ser. No. 10/228,542, the disclosure of which is hereby incorporated by reference.

The instant deposition apparatus provides for the continuous formation or deposition of a polycrystalline material on a mobile discrete or continuous web substrate. The instant deposition apparatus and process provide for a continuous manufacturing capability of polycrystalline materials. Deposition or formation of a polycrystalline material occurs on a continuously moving or continuously transported substrate within the instant deposition apparatus, where the substrate may be a discrete or continuous web substrate as described hereinabove. Continuous motion of a discrete or continuous web substrate distinguishes the instant deposition apparatus and process from the batch processes conventionally used to form polycrystalline materials.

Mobile substrate materials suitable for the instant invention include glass, stainless steel, and plastics. Instant substrates also include plastic coated substrates (e.g. kapton coated stainless steel) and plastic substrates having metal edges or strips attached thereto where the metal edges or strips engagingly contact a substrate or web transport mechanism to facilitate its advance within and through the instant deposition apparatus. Thicknesses of steel and plastic substrates may be thick or thin, thereby enabling deposition on rigid or flexible substrates. Representative plastics that can be provided in continuous web or discrete form include polyesters (e.g. PET), polyimides (e.g. kapton), polyetheretherketone (PEEK), polyethersulfone (PES), polyetherimide (PEI), polyethylenenaphthalate (PEN) and related materials. Plastic substrate are lightweight and desirable for supporting polysilicon based electronic devices in applications such as flat panel displays, active matrix displays, liquid crystal displays etc. Lightweight displays and devices may also be obtained through depositions of polysilicon (alone or in combination with other layers or devices) on a plastic coated steel substrate followed by subsequent etching of the steel to leave a plastic support display or assembly of electronic devices based on polysilicon.

Upon dispensation from the pay-out unit, one or more mobile substrates enter the deposition unit and are transported therethrough toward the take-up unit. The deposition unit includes one or a series of operatively connected deposition chambers, each of which has conditions established for the deposition of a thin film layer of an intended composition and thickness for a given web transport speed. The deposition chambers within a series are isolated from each other to prevent cross-contamination and may utilize different deposition or material formation techniques. As a result, the formation of multilayer thin film structures comprising a plurality of thin film compositions and thicknesses are achievable with the instant deposition apparatus. In addition to the deposition method and/or conditions, film thickness is also influenced by the web transport speed with slower speeds generally providing thicker films. Depending on the rate of thin film layer formation and the kinetics of the physical and/or chemical processes associated with deposition, layer composition may also depend on web transport speed.

A variety of thin film deposition methods may be used in the instant deposition apparatus. Methods including chemical vapor deposition, plasma enhanced chemical vapor deposition, physical vapor deposition, sputtering and vacuum deposition are within the scope of the instant invention.

The instant deposition unit may also include one or more processing chambers or means for processing within a deposition chamber for processing or otherwise altering as-deposited thin film layers. Processing functions may include deposition of additional layers or materials (e.g. masking layers, photoresists, contacts etc.), modifications of the physical dimensions, coverage, or shape of layers (e.g. etching, thinning, polishing), or modifications of the phase or structure of a material included in a layer. Processing techniques may include embossing, photolithography, etching, thermal annealing, laser annealing, patterning and selective deposition (e.g. ink-jet printing).

The instant deposition apparatus includes at least one chamber for depositing a polycrystalline material or for depositing a material that can be transformed to a polycrystalline material in a processing chamber or through processing means including in the instant deposition apparatus. In a preferred embodiment, polysilicon is deposited or a material that can be transformed to polysilicon is deposited where a processing chamber or processing means for effecting the transformation to polysilicon is included within the instant continuous deposition apparatus. In a preferred embodiment, the instant deposition apparatus includes a deposition chamber for depositing amorphous or microcrystalline silicon and a processing chamber or means for processing that transforms amorphous or microcrystalline silicon into polysilicon. In another preferred embodiment, the instant deposition apparatus includes a deposition chamber for depositing amorphous or microcrystalline SiGe and a processing chamber or means for processing that transforms amorphous or microcrystalline SiGe into polycrystalline SiGe.

In a preferred embodiment, deposition of amorphous or microcrystalline silicon or SiGe is accomplished through plasma enhanced chemical vapor deposition (PECVD). PECVD is a plasma assisted deposition process. Glow discharge is one example of a plasma assisted deposition process. In PECVD deposition, a plasma is created in a deposition chamber in a plasma region between a grounded web or discrete substrate and a cathode positioned in close proximity to the web or substrate. The plasma region represents the region in space in which a plasma may be formed. When a plurality of webs or substrates is utilized, the plasma region preferably extends over each web or substrate within the plurality.

In a preferred embodiment, the cathode surfaces are substantially planar and rectangular in shape. In a typical configuration, the cathode is connected to an electrical power supply that provides the electrical or electromagnetic energy necessary to establish and maintain a plasma in the plasma region between the cathode and deposition surfaces of continuous webs or discrete substrates. The power supply may be an AC power supply that introduces AC energy in the radiofrequency or microwave range, but may also be a DC power supply. In a preferred embodiment, an AC power supply operating at 13.56 MHz is used. Radiofrequency (including VHF frequencies (ca. 5-100 MHz)) and microwave frequencies (ca. 100 MHz-300 GHz; e.g. 2.54 GHz) may generally be used in the PECVD deposition of amorphous and microcrystalline silicon.

A plasma is created from process gases that enter the plasma region between the cathode and web or discrete substrate while the power supply is operating or while electromagnetic energy is otherwise being introduced to the plasma region. Process gases include deposition precursors, the feed gases that react or are otherwise transformed into the reactive species required to form a film on a deposition surface during PECVD processing. When depositing amorphous or microcrystalline silicon, deposition precursors such as silane (SiH₄), disilane (Si₂H₆), SiF₄, or (CH₃)₂SiCl₂ may be used. Deposition precursors may also include doping precursors such as phosphine, diborane, or BF₃ for n or p type doping. Process gases may also include carrier gases, such as inert or diluent gases, including hydrogen, which may or may not be incorporated in a deposited thin film.

During PECVD processing, the reactive species deposit on the web or substrate to provide material used to form a layer. PECVD deposition and processing can occur with a single process gas or deposition precursor or with a plurality of process gases or deposition precursors, depending on the intended composition, thickness and/or growth mechanism of the deposited thin film. Process gases may be introduced via valves and gas lines connected to the deposition unit or chamber and may also be introduced through openings within the cathode. The delivery of process gases may also occur through the cathode as described in U.S. patent application Ser. No. 10/043,010 entitled “Fountain Cathode for Large Area Plasma Deposition” assigned to the instant assignee, the disclosure of which is hereby incorporated by reference. In one embodiment, a gas manifold is used to provide process gases. The isolation of deposition chambers to minimize cross-contamination in multilayer depositions may be accomplished, for example, as described in U.S. Pat. No. 5,374,313 to the instant assignee; the disclosure of which is also hereby incorporated by reference.

Examples of plasma assisted deposition of amorphous and microcrystalline silicon are described in U.S. Pat. Nos. 4,542,711; 4,485,125; 4,423,701; 4,600,801; 4,609,771; and 5,977,476; the disclosures of which are hereby incorporated by reference. U.S. Pat. Nos. 4,542,711 and 4,485,125 disclose a multiple chamber apparatus for the continuous production of tandem silicon photovoltaic cells on a web substrate using a plasma deposition method. U.S. Pat. No. 4,423,701 discloses a multiple chamber glow discharge apparatus having a non-horizontally disposed cathode for the deposition of thin film layers onto discrete plates or continuous web substrates. U.S. Pat. No. 4,423,701 further discloses deposition onto two continuous web substrates in which the two webs are disposed on opposite sides of a cathode. U.S. Pat. Nos. 4,600,801; 4,609,771 and 5,977,476 disclose microcrystalline n-type and p-type silicon materials in photovoltaic devices and in combination with amorphous silicon.

In one embodiment of the instant deposition apparatus, an as-deposited layer of amorphous silicon is transformed into polysilicon. Formation of polysilicon involves a crystallization of amorphous silicon and may be achieved by processing steps that include the controlled introduction of energy. Energy is required to induce the atomic motions and rearrangements necessary for the nucleation and growth of a crystalline or polycrystalline phase from an amorphous phase. The introduction of energy leads to an overall or localized heating of amorphous silicon to a temperature that is sufficiently high to permit formation of a crystalline phase. Since crystallization is typically a kinetically limited phenomenon, the temperature necessary to induce formation of a crystalline phase may vary depending on the time available for crystallization. The minimum temperature at which crystallization may occur may be referred to as the crystallization temperature. At the crystallization temperature, crystallization may occur, but does so over an extended, often impractically long, period of time. As the temperature is increased above the crystallization temperature, the time required for crystallization decreases. Since the crystallization temperature is less than the melting temperature of amorphous silicon, crystallization of amorphous silicon may occur at temperatures below the melting temperature.

Crystallization of amorphous silicon may also be achieved by heating amorphous silicon to a temperature at or above its melting temperature. Once melted, a crystalline, microcrystalline or polycrystalline phase may be formed by allowing the melt to cool at a sufficiently slow rate. As is known in the art, rapid cooling or quenching of a melt phase may produce an amorphous phase, while slower cooling permits formation of a crystalline, microcrystalline or polycrystalline phase. The rate of cooling (or dissipation of heat) of a melt phase influences the nature of the crystalline phase formed. Under practical conditions, polycrystalline silicon (polysilicon) or microcrystalline silicon, rather than single crystalline silicon, forms upon cooling a melt phase of amorphous silicon or an amorphous silicon phase heated to a temperature of at least the crystallization temperature. Microcrystalline silicon and polysilicon comprise grains of crystalline silicon (crystallites), where the grain size and distribution thereof in a particular sample are dependent upon the conditions under which nucleation and crystallization occur. The grains may also aggregate to form particles. Grain sizes in microcrystalline silicon are typically on the order of tens to a few hundred angstroms, while grain sizes in polysilicon typically range from at or above a few hundred angstroms to micron length scales. Factors such as the temperature at which crystallization was induced (e.g. whether crystallization is induced at the crystallization temperature, melt temperature, a temperature between the crystallization and melt temperatures, or a temperature above the melt temperature), the cooling rate, the length of time the sample is held at a particular temperature, the temperature profile within a layer or sample of amorphous silicon, the presence of impurities etc. influence the grain size, state of aggregation of grains and particle size, spatial distribution of grain sizes, range of grain sizes present in a particular sample etc. Generally, slower cooling rates promote the formation of larger grains. From the point of view of electronic devices, polysilicon is preferred over microcrystalline silicon because the mobility of charge carriers increases with increasing grain size. By controlling the processing temperature, energy input, and heat dissipation rate it is possible to selective form microcrystalline silicon or polysilicon from amorphous silicon.

In another embodiment of the instant invention, an as-deposited layer of microcrystalline silicon is transformed into polysilicon. As described hereinabove, microcrystalline silicon comprises crystalline grains of silicon having small dimensions and has electronic properties (electron and hole mobilities, defect concentrations, etc.) that are inferior to those of polysilicon. Conversion of microcrystalline silicon to polysilicon requires an enlargement of the grain size and may be accomplished through the controlled introduction of energy. Grain enlargement may occur through melting and recrystallizing or through fusion of impinging grains. Melting requires providing energy in an amount sufficient to heat a layer of microcrystalline silicon or a portion thereof to or above its melting temperature followed by cooling at a rate conducive to the formation of enlarged grains to form polysilicon. Fusion of impinging grains may occur at temperature below the melting temperature. As indicated hereinabove, crystallization may be induced by heating to a temperature of at least the crystallization temperature. Such heating may cause grain enlargement through crystal homogenization at the interface between adjacent grains. Available thermal energy induces atomic motions and grain reorientations to provide crystal lattice continuity across grain boundaries and the merging of adjacent grains.

Polycrystalline materials may generally be formed in the instant deposition apparatus by depositing a layer of amorphous or microcrystalline material having substantially the same composition as the polycrystalline material that one seeks to form and transforming the layer of amorphous or microcrystalline material to form a layer of polycrystalline material. The transformation generally involves the addition of energy, preferably thermal energy, to the deposited amorphous or microcrystalline layer. The transformation includes an enlargement of the grain size of an as-deposited layer of amorphous or microcrystalline material and may also include a nucleation of a crystalline phase. The purpose of the transformation step is to obtain a material having a larger average grain size than an as-deposited layer of amorphous or microcrystalline material. Further discussion of the transformation is provided hereinbelow using polysilicon as a representative polycrystalline material. Other polycrystalline materials may be analogously formed.

In one embodiment of the instant deposition apparatus, amorphous silicon or microcrystalline is deposited and may be transformed into polysilicon by providing energy in a processing step. The amorphous or microcrystalline silicon that is transformed may be undoped, n-type or p-type so that undoped, n-type or p-type polysilicon may be formed during the transformation of amorphous or microcrystalline silicon. The transformation processing step may be completed in the deposition chamber in which an amorphous silicon layer is formed or in a separate processing chamber. Energy may be provided in the form of thermal energy, optical energy or a combination thereof. Energy may also be provided in other forms (e.g. electrical energy, electromagnetic beam energy, electron beam energy etc.) that lead to overall or localized heating of an amorphous or microcrystalline silicon layer.

In one preferred embodiment herein, thermal energy is provided to an amorphous or microcrystalline silicon layer to effect its transformation to polysilicon. The thermal energy may be provided by a conventional heat source such as a heat lamp, furnace or a Xe lamp or may be provided by an optical source such as a laser. In one embodiment, thermal energy is provided in a rapid thermal annealing process. In rapid thermal annealing, a heat source is applied to an amorphous or microcrystalline silicon layer to increase its temperature and subsequently removed to permit cooling and crystal nucleation and/or growth. The heat source may be a continuous source that is turned on and off, shuttered or otherwise modulated or a transient (pulsed) source. Acceptable heat sources include laser or electron beams, flashlamps, tungsten-halogen lamps, arc discharge lamps (e.g. Xe lamp), and furnaces. The heat source may be focused and localized or may broadly heat or illuminate a discrete substrate or portion thereof or a large area or portion of a continuous web substrate. A focused or localized heat source may also be rastered across a substrate to effect rapid thermal annealing over selected areas. By controlling the intensity, duration, wavelength, pulse characteristics, power etc. of the heat source, it is possible to control the maximum temperature reached in an amorphous or microcrystalline silicon layer (e.g. temperatures above the melting temperature or between the melting and crystallization temperatures etc. can be produced in an amorphous or microcrystalline silicon layer), the length of time the layer is held at that temperature, the temperature distribution within a layer, the heat up and cool down rates etc. to control the grain size of polysilicon formed.

In an embodiment of the instant invention, laser annealing is used to transform amorphous or microcrystalline silicon to polysilicon. In laser annealing, energy from a laser beam is used to induce a transformation of amorphous or microcrystalline silicon to polysilicon. The laser provides thermal and optical energy and heats amorphous or microcrystalline silicon to at least the crystallization temperature to induce formation of polysilicon. A continuous wave or pulsed laser may be used. By controlling the laser intensity, duration, pulse characteristics (e.g. rise and fall times), and wavelength, it is possible to control the energy provided by a laser to a layer of amorphous or microcrystalline silicon as well as the temperature distribution within and across the layer and its time dependence. The grain size of polysilicon may thereby be controlled. In a preferred embodiment, a pulsed excimer laser (e.g. XeCl) having a pulse duration in the nanosecond range is used for laser annealing.

Polysilicon having grain sizes ranging from a few hundred angstroms to a few microns may be formed by the instant deposition apparatus. In a preferred embodiment, polysilicon is formed by depositing a layer of amorphous silicon and transforming it to polysilicon. In another preferred embodiment, polysilicon is formed by depositing a layer of microcrystalline silicon and transforming it to polysilicon where the resulting polysilicon has a larger average grain size than the as-deposited microcrystalline silicon. In a preferred embodiment, polysilicon having an average grain size of at least 100 nm is formed. In a more preferred embodiment, polysilicon having an average grain size of at least 500 nm is formed. In a most preferred embodiment, polysilicon having an average grain size of at least 1 micron is formed.

Processing steps used to effect a transformation of amorphous or microcrystalline silicon to polysilicon (e.g. heating, rapid thermal annealing, laser annealing, lamp annealing) may optionally be completed in the presence of an ambient gas or atmosphere. Transformations may be completed in oxidizing, reducing or inert atmospheres using ambient gases such as hydrogen, nitrogen, oxygen, argon, or helium. Processing in the presence of an ambient gas may influence the hydrogen content of the polysilicon layer formed as well as the defect type and density.

In a preferred embodiment, transformation of amorphous or microcrystalline silicon to polysilicon occurs in the presence of a hydrogen plasma. The hydrogen plasma provide hydrogen radicals that act to passivate defects present within the grains of or at the grains boundaries of polysilicon. As mentioned hereinabove, polysilicon comprises a plurality of grains. Individual grains typically include defects and additional defects are typically present at the boundaries between adjacent grains. The defects include dangling bonds at silicon atoms, vacancies, twinning, and SiH₂ defects. The presence of defects reduces the mobility of charge carriers in polysilicon and as a result, it is desirable to reduce the defect concentration of the polysilicon formed in the instant invention. A reduction in the defect concentration of polysilicon occurs through passivation of polysilicon.

In a preferred embodiment, passivation of defects results from the formation of polysilicon from amorphous or microcrystalline silicon in the presence of a hydrogen plasma. In an alternative embodiment, polysilicon is formed and subsequently subjected to a hydrogen plasma to achieve passivation. A hydrogen plasma may be formed in a PECVD reaction chamber from hydrogen gas. The hydrogen gas may be introduced during or after the formation of an amorphous or microcrystalline silicon layer to passivate as-deposited amorphous or microcrystalline layers where the as-deposited layers are subsequently transformed to polysilicon. Since the transformation to polysilicon may involve the formation of further defects, it is preferable to passivate polysilicon as it is being formed or after its formation. Heating or annealing of amorphous or microcrystalline silicon with lamps, lasers, furnaces or other heat sources may be accomplished in the presence of a hydrogen plasma. A hydrogen plasma formed from hydrogen gas comprises hydrogen radical species that include unbonded electrons that may combine with dangling bonds to form bonds and thereby passivate or otherwise remove a defect. Defects within grains and at grain boundaries may be passivated by a hydrogen plasma. Similarly, a layer of polysilicon may first be formed and subsequently subjected to treatment by a hydrogen plasma.

Also in accordance with the instant invention are embodiments in which a plurality of heat sources is used to induce a transformation of amorphous or microcrystalline silicon to polycrystalline silicon. Heat sources such as lamps, lasers or electron beams may be positioned at multiple positions within a deposition or processing chamber. Multiple heat sources may be used to provide broad heating or illumination over large area portions of a discrete or continuous substrate as well as to provide selected heating or illumination over specific portions. Use of a plurality of heat sources is preferred where individual heat sources provide heating over a limited area. Lasers used in laser annealing, for example, have beam diameters that may be small relative to the dimensions of a discrete or continuous substrate. By combining laser sources so that the beams from a plurality of laser sources overlap, annealing over wider areas is possible. A plurality of lamps may similarly be used. In one embodiment, a linear array of lasers or lamps is included in a deposition or processing chamber and is sufficiently long and overlapping to extend continuously across the width or lateral dimension of a mobile substrate. In this embodiment, the linear array of lasers or lamps may be positioned parallel to the leading edge of the mobile substrate so that the beams emanating from the array illuminate and effect a transformation across a lateral dimension of a mobile substrate. In a preferred embodiment, a linear array of lasers or lamps is positioned at or near the outlet of a deposition chamber. As a mobile substrate is transported, fresh amorphous or microcrystalline material is moved into the illumination field of a linear array of lasers or lamps and transformed to polysilicon. In this way, the full area of a layer of amorphous or polycrystalline silicon may be transformed to polysilicon. Linear arrays of non-overlapping heat sources may also be used in annealing. Non-overlapping arrays provide transformations of selected portions of a mobile substrate to polysilicon. Non-overlapping linear arrays may, for example, provide for a stripe-like pattern of polysilicon where regions of polysilicon alternate with regions of amorphous or microcrystalline silicon. Non-linear arrays or combinations of heat sources may also be used to provide additional flexibility in the selective transformation of amorphous silicon or microcrystalline silicon to provide patterned regions of polysilicon within amorphous or microcrystalline silicon on mobile substrates. Selected pulsing or time sequencing of lasers or lamps within an array provides further degrees of freedom in forming polysilicon patterns.

Also within the scope of the instant invention are embodiments in which heating, annealing or transformation of amorphous or microcrystalline silicon to form polysilicon is accomplished through the use of different types of heating sources. Furnace heating, for example, may be combined with laser annealing to effect a transformation to polysilicon and/or to control the grain size of polysilicon. Two step annealing processes (e.g. furnace heating followed by laser or lamp heating) are also within the scope of the instant invention where the two steps are completed independently and/or in separate chambers and/or at different times. Similarly, two step laser annealing processes in which the laser fluence in one laser annealing treatment differs from the laser fluence in another laser annealing treatment. A first laser annealing step using a low fluence laser followed by a second laser annealing step using a higher fluence laser, for example, is within the scope of the instant invention. Two step annealing processes may lead to a reduction in defect concentrations within or between grains of polysilicon and thereby improve the mobility of polysilicon.

Polysilicon may be formed in the instant deposition apparatus by depositing a layer of amorphous or microcrystalline silicon and converting it to polysilicon through the controlled introduction and removal of energy as described hereinabove. In a preferred embodiment, amorphous or microcrystalline silicon is deposited via a radiofrequency or microwave plasma enhanced chemical vapor deposition process using silane or disilane as deposition precursors. In another preferred embodiment, silane or disilane are introduced as deposition precursors in combination with hydrogen as a carrier gas.

The thickness of a polysilicon layer may be controlled by depositing a layer of amorphous or microcrystalline silicon of a particular thickness and transforming that layer in its entirety to polysilicon. Alternatively, a polysilicon layer of a desired thickness may be formed by building up polysilicon through a sequence of alternating deposition and transformation steps. In this sequence of steps, some amorphous or microcrystalline silicon is deposited and annealed or otherwise transformed to polysilicon. Additional amorphous or microcrystalline silicon next deposited on the polysilicon and subsequently transformed to form additional polysilicon, thereby increasing the thickness of polysilicon. This sequence of alternating deposition and transformation steps may be repeated as often as necessary to obtain a polysilicon layer of a desired thickness.

Formation of polysilicon through alternating deposition and transformation steps may be advantageous, especially in the formation thick layers of polysilicon, because this approach may provide better control over the temperature distribution within a volume of amorphous or microcrystalline silicon. As the thickness of a layer of amorphous or microcrystalline silicon increases, it becomes more difficult to control the temperature profile therein through the use of an external laser, lamp or other heat source. More particularly, as the thickness of a layer of amorphous or microcrystalline silicon increases, it becomes more difficult to control the temperatures in the interior of the layer. Heat provided by lasers, lamps or other heat sources primarily influence the temperature at the surface of a layer and have a more limited ability to penetrate and influence the interior of a layer. Other heat transfer mechanisms, such as conduction of heat from a surface region, tend to control the temperatures achieved in the interior of a layer and in portions of a layer not directly illuminated by a laser or lamp. These supplemental heat transfer mechanisms may be difficult to control and may occur on impractically long time scales to permit the desired degree of control over the temperature distribution within a layer and the resulting characteristics such as grain size of the polysilicon formed therefrom. Since thinner layers of amorphous or microcrystalline silicon have a greater relative proportion of surface portion to interior portion than thicker layers, greater control over the spatial and temporal temperature characteristics during annealing or transforming of amorphous silicon or microcrystalline silicon to polysilicon. An alternating sequence of deposition and transformation steps also provides for greater control over the grain size variation within a layer of polysilicon. The thickness of amorphous or microcrystalline silicon deposited may vary for different deposition steps within an alternating sequence and the annealing or temperature conditions may vary for different transformation steps in an alternating sequence. As a result, a distribution of different grain sizes within a layer of polysilicon may be created. Combinations of large grains and small grains, for example, may be formed.

An alternating sequence of deposition and transformation steps may be completed in a single chamber of the instant deposition apparatus or in a plurality of chambers. In a single chamber embodiment, a deposition chamber is equipped with means for annealing or heating a layer of amorphous or microcrystalline silicon on a discrete or continuous substrate. In this embodiment, the time of deposition of a portion of amorphous or microcrystalline silicon is less than the residence time of a discrete or continuous substrate in the chamber and transformation of the deposited portion of amorphous or microcrystalline silicon occurs before the deposited portion is transported out of the chamber. The deposition process and transformation or annealing process may be cycled on and off in an alternating fashion several times during the residence time of a discrete or continuous substrate in a single chamber to build up a polysilicon layer.

An alternating sequence of deposition and transformation steps may also be completed over a series of chambers that includes separate deposition and transformation processing chambers. An initial amount of amorphous or microcrystalline silicon may be deposited on a discrete or continuous web in a deposition chamber and transformed to polysilicon in a subsequent processing chamber to provide a first amount of polysilicon. The discrete or continuous web may thereafter be transported to additional deposition and processing chambers to form additional polysilicon to thereby increase the thickness of a polysilicon layer. A sequence of alternating deposition and transformation processing chambers may thus be used to form polysilicon layers of a desired thickness. Use of separate deposition and processing chambers may be beneficial since the operating conditions within each chamber may be maintained continuously and applied to new portions of an advancing discrete or continuous web substrate. This method avoids the need and potential complications that may accompany the transient cycling of deposition and/or transformation steps. A dedicated annealing chamber, for example, may provide more convenient and/or stable control of heating conditions or the temperature conditions within a layer since transient effects associated with turning a heat source on and off may be avoided. More uniform annealing conditions may therefore result and lead to a more uniform distribution of grain sizes in a layer of polysilicon when a more uniform layer is desired. The scope of this method also includes embodiments in which deposition and transformation occur in a given chamber and the thickness of polysilicon is controlled by transporting a discrete or continuous web substrate through a plurality of such chambers to build up a layer of polysilicon.

An alternating sequence of deposition and transformation steps may further include passivation steps. As described hereinabove, passivation leads to a reduction in the defect density within or at the boundaries of the grains of polysilicon. Passivation may be accomplished with a hydrogen plasma that is applied during the formation of amorphous or microcrystalline silicon, during the transformation of amorphous or microcrystalline silicon to polysilicon or after formation of polysilicon. Passivation may occur once or at multiple times during the build up of a layer of polysilicon having a desired thickness. Since passivation occurs preferentially at the surface of a region of polysilicon, multiple passivation steps may lead to an overall lower concentration of defects than a single passivation step since passivation deep into the interior of a layer of polysilicon may be difficult to achieve. Passivation within the bulk of a polysilicon layer requires the transport of passivating species through the layer and becomes more difficult as the thickness of the layer increases. Hence, passivation at intermediate points during the build up of a polysilicon layer may provide for a lower defect concentration and commensurately improved charge carrier mobility.

In the instant deposition apparatus, passivation may be completed in a deposition chamber, in a transformation chamber for forming polysilicon from amorphous or microcrystalline silicon, or in a separate processing chamber dedicated to passivation. Any chamber in the instant deposition may be equipped with means for forming a hydrogen plasma along with means for introducing hydrogen gas into the chamber. In a preferred embodiment, the hydrogen plasma is formed from hydrogen gas in a high intensity microwave plasma formation process.

In addition to polysilicon, the transformation processes described hereinabove may also be used to effect the formation of polycrystalline silicon-germanium (SiGe) alloys. Inclusion of a germanium deposition precursor in a deposition chamber permits formation of amorphous or microcrystalline SiGe alloys where the alloy composition may formally be written Si₁₋ₓGeₓ and where alloy compositions ranging continuously from pure Si (x=0) to pure Ge (x=1) are possible. Germane (GeH₄) is a preferred germanium deposition precursor and can be used in combination with silane, disilane or other silicon deposition precursors known in the art to form amorphous or microcrystalline SiGe alloys in a chemical vapor deposition or plasma enhanced chemical vapor deposition process. The formation of SiGe alloys in a microwave plasma enhanced chemical vapor deposition process has been discussed in U.S. Pat. Nos. 4,521,447 and 4,517,223, the disclosures of which are hereby incorporated by reference. As in the formation of polysilicon, the formation of polycrystalline SiGe alloys involves the application of energy to induce the nucleation and/or growth of grains. Enlargement of grains provides better charge carrier mobilities.

In the instant deposition apparatus, polycrystalline SiGe alloys may be formed by first forming a layer of amorphous or microcrystalline SiGe alloy and subsequently transforming the layer to its polycrystalline form using the heating or annealing methods described hereinabove for the formation of polysilicon from amorphous or microcrystalline silicon. Furnace heating, lamp heating, rapid thermal annealing, laser annealing, etc. may all be used to form polycrystalline SiGe alloy from an amorphous or microcrystalline SiGe layer. As in the case of polysilicon described hereinabove, polycrystalline SiGe alloy layers may be formed in a single deposition step followed by a single transformation step or through an alternating sequence of deposition and transformation steps to build up a layer of a desired thickness. The defect concentration of polycrystalline SiGe alloy may also be reduced through treatment with a hydrogen plasma during formation of amorphous or microcrystalline SiGe alloy, during transformation of amorphous or microcrystalline alloy to polycrystalline SiGe alloy, or after formation of polycrystalline SiGe alloy.

In addition to the formation of polysilicon or polycrystalline SiGe alloys, the instant deposition apparatus may be used to form device structures that include a polysilicon and/or polycrystalline SiGe alloy layer. These device structures include other layers (e.g. dielectric layers, barrier layers, chalcogenide layers, metal layers, electrical contacts) in combination with a polysilicon or polycrystalline SiGe layer. Thin film layers with a variety of compositions, properties and thicknesses ranging from tens of angstroms to a few thousand angstroms are achievable with the instant deposition apparatus. The ability to include deposition chambers within the instant deposition apparatus that utilize different deposition techniques affords tremendous flexibility in controlling the composition and properties of deposited films and provides a range of device structures that include polysilicon or polycrystalline SiGe in a continuous deposition apparatus.

Conducting, semiconducting, and non-conducting thin film layers, for example, may be formed in the deposition unit of the instant invention. In a preferred embodiment, thin film layers including polysilicon or polycrystalline SiGe are formed in deposition chambers utilizing radiofrequency or microwave PECVD deposition to form amorphous or microcrystalline silicon or SiGe where amorphous or microcrystalline silicon or SiGe is transformed in the deposition apparatus as described hereinabove to polysilicon or polycrystalline SiGe. High deposition rates, particularly using microwave PECVD are achievable. Microcrystalline silicon, for example, can be deposited at a rate of 20 Å/s and amorphous silicon may be deposited at a rate of 200 Å/s. N-type, intrinsic, and p-type forms of polysilicon and polycrystalline SiGe may be formed in the instant continuous deposition apparatus. Radiofrequency or microwave PECVD may also be used to form dielectric materials within device structures. SiOₓ or SiN may be formed at rates of 200-300 Å/s in a microwave PECVD process over a continuous web having a width of 30 cm. Chemical vapor deposition in the absence of a plasma may also be used to form amorphous or microcrystalline silicon, SiGe alloys, SiOₓ, or SiN.

Metal or conducting layers or regions may be deposited through a sputtering (e.g. dc magnetron sputtering) or physical vapor deposition (PVD) process. Sputtering or PVD may be accomplished in independent chambers in the instant deposition apparatus or within PECVD or CVD deposition chambers by incorporating conventional sputtering or PVD apparatus into such chambers. Sputtering is a process in which a solid target that contains or is otherwise capable of forming an intended thin film composition is ablated by bombardment with energetic ions from a low pressure plasma struck in a gas. Ejected material from the target, typically in the form of ionized atoms or clusters, passes to a discrete substrate or continuous web where a sputtered film of or from the target material is formed. Generally, the sputtered film has a chemical composition that matches or is similar to that of the target material. The sputtering of an Ag target, for example, produces an Ag sputtered film. The plasma may be formed from a chemically inert gas such as Ar, a reactive gas such as O₂ or H₂, or a combination of inert and reactive gases. When a reactive gas is used, the sputtered film may include a chemical compound formed from a reaction of the target material and reactive gas. The transparent conducting oxide ZnO, for example, may be formed by sputtering a Zn target in the presence of O₂. Other transparent conducting oxides may be similarly formed (e.g. ITO, SnO₂). Al, Ag and other metals may be deposited by sputtering and may be included as electrode materials in a device structure. Physical vapor deposition may be accomplished through reactive sputtering or evaporation methods.

An independent deposition chamber that utilizes sputtering as the deposition technique may hereafter be referred to as a sputtering chamber. A sputtering chamber includes a target and means for sputtering the target to form a sputtered thin film on a discrete substrate or continuous web. The sputtering means includes means for forming a plasma between the target and discrete substrate or web from a chemically inert or reactive gas introduced into the sputtering chamber. Plasma formation may be accomplished in the manner described hereinabove in the context of the PECVD deposition technique. Sputtering means may also be combined with other deposition techniques in a given deposition chamber. A PECVD deposition chamber, for example, may also include sputtering means and provide for deposition of layers of different compositions using PECVD to deposit one layer and sputtering to deposit another layer.

The thicknesses of the thin film layers formed by the instant deposition apparatus may be controlled by controlling the conditions within the deposition chambers of the instant deposition apparatus or by controlling the speed of web transport. Relevant experimental variables depend on the selected method of deposition. During PECVD film formation, for example, factors such as the flow rates of process gases, deposition precursors or doping precursors; temperature of deposition; distance between webs or substrates and cathode; and plasma strength may influence the rate of film formation and the thickness of the resulting film at a particular web transport speed. For a particular set of deposition conditions, the web transport speed or substrate exposure time may also influence thin film thickness. Slower transport speeds imply that a web resides in the plasma region for a longer time and this generally leads to thicker films. During a sputtering process, for example, factors such as the applied voltage, target composition, target location and chamber pressure may influence the rate of film formation. Thin films with thicknesses ranging from tens of angstroms to thousands of angstroms are achievable with the instant deposition apparatus.

By including a plurality of deposition chambers that may utilize different deposition techniques in the instant deposition unit, it is possible to form multilayer thin film structures including a layer of polysilicon and/or polycrystalline SiGe in which a plurality of thin film layers with a range of compositions and/or thicknesses are deposited on continuous webs or discrete mobile substrates. As used herein, the terms “a thin film layer deposited on a web substrate”, “a thin film layer formed on a continuous web”, “a thin film present on a web” and equivalents thereof as well as equivalents thereof for discrete substrates refer to a thin film layer supported by a web or substrate and may or may not mean that the film is in physical contact with the web or substrate. The first layer formed in the deposition unit is in physical contact with the web or substrate. If a plurality of deposition chambers is included in the deposition unit, additional layers may be formed. These additional layers may be formed directly over thin film layers that have been formed in preceding deposition chambers and may lack direct physical contact with a web or substrate. Nonetheless such films shall be referred to herein as being on the web or substrate since they are supported by the web or substrate. All of the layers of a sequential multilayer structure, for example, in which the layers ascend away from the web or substrate are referred to herein as being on the web or substrate even when not all of the layers are in physical contact with the web or substrate.

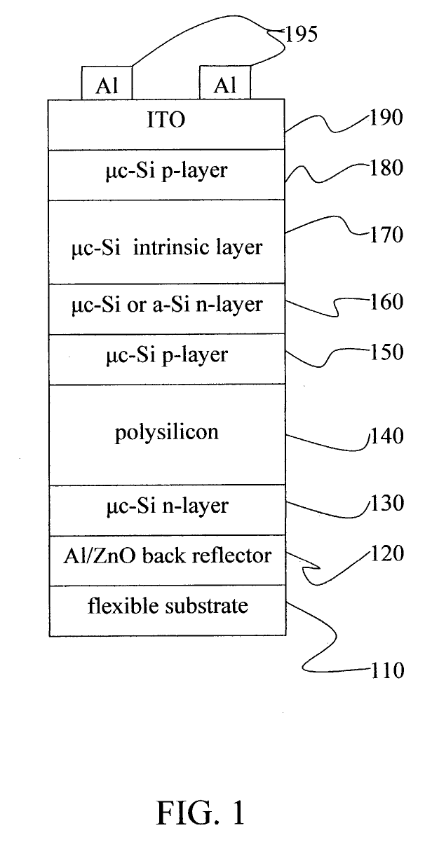

Multilayer structures such as those required for photovoltaic devices, solar cells, p-n junctions, nip structures and chalcogenide electronics that include a polysilicon or polycrystalline SiGe layer may be deposited on a discrete substrate or continuous web with the instant deposition apparatus. A representative device structure that may be formed with the instant deposition apparatus is shown in FIG. 1. The device is a tandem solar cell that includes a polysilicon layer. The tandem cell includes a stacking of two nip structures. The device includes a flexible substrate (e.g. plastic) 110, an Al/ZnO back reflector layer 120, an n-type microcrystalline silicon layer 130 (with thickness of e.g. 200 Å), an intrinsic polysilicon layer 140, a p-type microcrystalline silicon layer 150 (with thickness of e.g. 250 Å), a n-type amorphous or microcrystalline silicon layer 160 (with thickness of e.g. 200 Å), an intrinsic microcrystalline silicon layer 170 (with thickness of e.g. 800 Å), a p-type microcrystalline silicon layer 180 (with thickness of e.g. 250 Å), a transparent conducting oxide layer (ITO (indium tin oxide)) 190, and a top electrode 195 comprising an Al grid. In this structure, the microcrystalline silicon layer 170 and the polysilicon layer 140 are the primary sunlight absorbing layers in the structure. The layer 170 absorbs the shorter wavelength portions of the solar spectrum and the polysilicon layer absorbs the longer wavelength (e.g. red) portions of the spectrum. Use of polysilicon in the device structure shown in FIG. 1 is advantageous because it obviates the need to include a red absorbing SiGe alloy layer thereby avoiding the higher costs and additional process complexities associated with using a germanium deposition precursor.

In the formation of the device structure shown in FIG. 1, a flexible substrate is provided by a pay-out unit of the instant deposition apparatus and transported to a deposition chamber that forms the back reflector layer 120 in a sputtering process. The n-type microcrystalline silicon layer 130 is next formed in a PECVD process using, for example silane along with phosphine as an n-type doping precursor. Formation of layers 120 and 130 may occur in the same or separate chambers. The polysilicon layer 140 is formed through a sequence of deposition and transformation steps in a layer by layer crystallization process as described hereinabove. A 1-2 micron thick polysilicon layer, for example, may be formed by depositing a thin layer (e.g. 100-200 nm) of amorphous or microcrystalline silicon deposited by PECVD, crystallizaing the layer through heating or annealing using lasers or lamps as described hereinabove in a single chamber or plurality of chambers, and repeating the deposition and crystallizing steps until the desired thickness of polysilicon is obtained. Crystallization may occur in the same chamber as the deposition or in a separate chamber. The polysilicon layer formed may subsequently be subjected to a hydrogen plasma treatment step as described hereinabove to reduce the defect concentration. Alternatively, hydrogen plasma treatment steps may occur periodically during the build up of the polysilicon layer. The p-type microcrystalline silicon layer 150, the n-type microcrystalline or amorphous silicon layer 160, the intrinsic microcrystalline silicon layer 170, and the p-type microcrystalline silicon layer 180 may next be formed in succession by transporting the flexible web substrate through a series of PECVD deposition chambers. Phosphorous and boron may be used as n-type and p-type dopants, respectively, and included as deposition precursors in the form of phosphine and BF₃. The transparent conducting oxide (ITO) layer 190 may be formed in a sputtering chamber following the PECVD deposition chamber in which the p-type microcrystalline layer 180 is formed or alternatively, the sputtering may occur in that PECVD deposition chamber. The Al grid 195 may be formed in a final sputtering or physical vapor deposition step before transporting the mobile flexible substrate to a take-up unit.

Similarly, tandem devices containing a SiGe alloy layer or devices including a plurality of nip structures may be formed where the thickness and/or composition of each type of layer may be varied. Triple cells including i-type layers having different compositions (e.g. different alloys of silicon and germanium) and different bandgaps, for example, may be formed. Similarly, n-type layers that are microcrystalline or p-type layers that are amorphous are among the layers that may be formed. Composite layers such as an n-type layer that includes an amorphous sub-layer and a microcrystalline sub-layer are also possible.

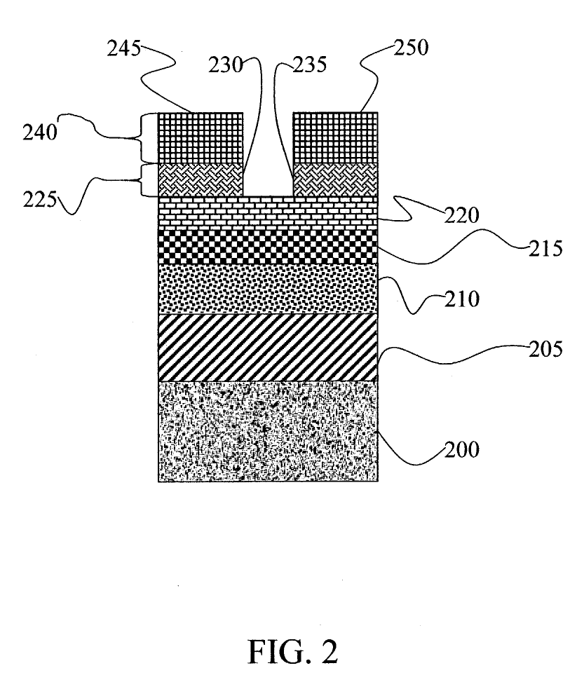

Thin film transistors (TFTs) that include a polysilicon or polycrystalline SiGe layer are further representatives of the device structures that can be formed in a continuous process using the instant deposition apparatus. Polysilicon or polycrystalline SiGe may be included in the source, drain or gate regions of a TFT. Top gate or inverted, as well as self-aligned and non-self-aligned TFT structures can be formed in different embodiments of the instant deposition apparatus. A representative TFT structure according to the instant invention is shown in FIG. 2, which shows a TFT deposited on a kapton (polyimide) substrate in a roll-to-roll process. The TFT of FIG. 2 includes a kapton substrate 200, a protective insulating layer 205 (typical thickness ca. 1000-5000 nm), a gate electrode that includes a metal contact 210 (typical thickness ca. 100 nm) and gate insulator 215 (typical thickness ca. 20-50 nm), an intrinsic silicon layer 220 (typical thickness ca. 50 nm), a patterned n⁺-silicon layer 225 (typical thickness ca. 20-50 nm) that includes source region 230 and drain region 235, and a metal layer 240 (typical thickness ca. 500 nm) that includes contacts 245 and 250. The protective insulator layer 205 may be comprised of oxides (e.g. SiO₂, SiOₓ), nitrides (e.g. SiNₓ) or a combination thereof that may be deposited on a mobile kapton substrate in the instant deposition apparatus through sputtering, CVD or PECVD processes. The insulating layer 205 acts to thermally insulate or protect the kapton substrate from processing temperatures sufficient to thermally damage it. Plastic substrates generally have low melting points and may soften at temperatures below the melting point and consequently, become unsuitable above a particular processing temperature. In the case of kapton, it is preferable that it not be subjected to a processing environment in any of the deposition chambers that causes its temperature to exceed ca. 275° C. The protective insulating layer 205 provides a thermal barrier that minimizes the temperature experienced by the kapton substrate during processing. Use of the insulating layer 205 permits processing or deposition of other layers in the structure at temperatures that exceed the upper stability temperature (ca. 275° C.) of kapton by inhibiting transfer of thermal energy to the kapton. If the processing or deposition time is less than the time required for thermal equilibration, the kapton substrate will remain at a temperature below the ambient or local temperature associated with a deposition or processing step.

A gate electrode comprising a metal contact 210 and gate insulator 215 is formed on the insulating layer 205. The metal contact may be formed through sputtering, PVD, CVD or PECVD. The gate insulator is typically an oxide, nitride or oxynitride of silicon and may be formed through sputtering, CVD or PECVD. The intrinsic silicon layer 220 may be polysilicon, microcrystalline silicon or amorphous silicon. If polysilicon is used, it is formed by first depositing microcrystalline or amorphous silicon and subsequently transforming it to polysilicon as described hereinabove. As described hereinabove, the transformation may occur through a heating or annealing step using laser, lamps, furnaces etc. It is preferable to form polysilicon at high temperatures since high temperatures are conducive to the formation of larger grains. In order to minimize thermal damage to the kapton substrate 200, it is preferable for annealing or heating to be localized in the layer 220 during the formation of polysilicon. As a result, localized laser annealing instead of broad heating with conventional lamps or furnaces is the preferred method of formation of polysilicon when using a plastic substrate. Laser annealing provides localized temperatures in the layer 220 without creating high temperatures in the surrounding ambient of a deposition chamber. Localized temperatures produced in amorphous or microcrystalline silicon during laser annealing may be well in excess of the upper stability temperature of a plastic substrate and yet not damage the plastic substrate due to the localized nature of the annealing and thermal dissipation through the barrier layer 205. Localized temperatures of several hundred to over a thousand degrees may be produced during laser annealing of an amorphous or microcrystalline silicon layer. Temperatures sufficient to melt amorphous or microcrystalline silicon may be generated by laser annealing in the formation of polysilicon without damaging the underlying plastic substrate.

Selective transformation of amorphous or microcrystalline silicon may also be accomplished in the instant deposition apparatus through a masking technique. A masking material (e.g. SiO₂ or SiNₓ) may be formed over a layer of amorphous or microcrystalline silicon and selective etched to expose selected portions thereof. Masking materials amenable to photolithography may also be used. Polymeric masking materials deposited via ink jet printing or nanoimprint lithography may also be used. The exposed portions of a masked area may subsequently be laser annealed to form polysilicon to produce a patterned layer 220 that includes polysilicon regions of selected lengths, shapes etc. within an otherwise amorphous or microcrystalline silicon layer. In practice, the entire layer 220 need not be transformed to polysilicon to achieve the beneficial mobility effects of polysilicon in a TFT structure. Instead, only those portions over which charge carriers migrate need to be polysilicon to benefit from the increased mobility of polysilicon. In one embodiment, the conductive channel of the TFT in the layer 220 that extends between the source region 230 and drain region 235 is polysilicon. Masking may be used to locally form polysilicon in this channel region. In a preferred embodiment, the polysilicon formed in the conductive channel includes grains that are oriented or elongated in a direction parallel to current flow so that carrier mobility is optimized. Unidirectional laser annealing may be used to shape and orient grains.

Once the layer 220 is formed and any masking material is removed, an n⁺-silicon layer 225 and a metal layer 240 are deposited thereon. The n⁺-silicon layer may include amorphous silicon, microcrystalline silicon or polysilicon and may be formed by CVD or PECVD. The metal layer may be deposited by PVD, sputtering, CVD or PECVD. The n⁺-silicon layer 225 and metal layer 240 may be further patterned to form source region 230, drain region 235 and metal contacts 245 and 250. The patterning may be achieved by forming a mask over the layer 240, removing a portion thereof to expose a portion of the metal layer and etching the metal layer and n⁺-silicon layer.

The depositions, heating or annealing, masking and patterning required to form the TFT of FIG. 2 may be achieved in a roll-to-roll fashion using the instant continuous deposition apparatus by providing deposition or processing chambers as needed to form and pattern layers in the required sequence needed to form a TFT on a mobile discrete or continuous web substrate. In addition to amorphous, microcrystalline or polysilicon, corresponding embodiments that include amorphous, microcrystalline or polycrystalline SiGe alloys are also within the scope of the TFT structures provided by the instant deposition apparatus.

Deposition of chalcogenide materials and the formation of device structures including chalcogenide materials in combination with amorphous silicon or SiGe, microcrystalline silicon or SiGe, polysilicon or polycrystalline SiGe. Chalcogenide materials are materials that include an element from column VI (the chalcogen elements) of the periodic table. Representative chalcogenide materials are those that include one or more elements from column VI of the periodic table and optionally one or more chemical modifiers from columns III. IV or V. One or more of S, Se, and Te are the most common chalcogen elements included in the chalcogenide materials formed in the instant deposition apparatus. The chalcogen elements are characterized by divalent bonding and the presence of lone pair electrons. The divalent bonding leads to the formation of chain and ring structures upon combining chalcogen elements to form chalcogenide materials and the lone pair electrons provide a source of electrons for forming a conducting filament. Materials that include Ge, Sb, and/or Te, such as Ge₂Sb₂Te₅, are examples of chalcogenide materials in accordance with the instant invention.

Trivalent and tetravalent modifiers such as Al, Ga, In, Ge, Sn, Si, P, As and Sb enter the chain and ring structures of chalcogen elements and provide points for branching and crosslinking. The structural rigidity of chalcogenide materials depends on the extent of crosslinking and leads to a broad classification of chalcogenide materials, according to their ability to undergo crystallization or other structural rearrangements, into one of two types: threshold materials and memory materials. Threshold materials generally possess a higher concentration of modifiers and are more highly crosslinked than memory materials. They are accordingly more rigid structurally. Threshold materials are amorphous and show little or no tendency to crystallize because the atomic rearrangements requited to nucleate and grow a crystalline phase are inhibited due to the rigidity of the structure. Threshold materials remain amorphous upon removing the applied voltage after switching. Memory materials, on the contrary, are lightly crosslinked and more easily undergo full or partial crystallization.

The properties of chalcogenide materials have been previously discussed and include switching effects such as those exploited in OTS (Ovonic Threshold Switch) devices. The OTS has been described in U.S. Pat. Nos. 5,543,737; 5,694,146; and 5,757,446; the disclosures of which are hereby incorporated by reference, as well as in several journal articles including “Reversible Electrical Switching Phenomena in Disordered Structures”, Physical Review Letters, vol. 21, p.1450-1453 (1969) by S. R. Ovshinsky; “Amorphous Semiconductors for Switching, Memory, and Imaging Applications”, IEEE Transactions on Electron Devices, vol. ED-20, p. 91-105 (1973) by S. R. Ovshinsky and H. Fritzsche; the disclosures of which are hereby incorporated by reference. Chalcogenide materials have been discussed in U.S. Pat. Nos. 5,166,758; 5,296,716; 5,534,711; 5,536,947; 5,596,522; and 6,087,674; the disclosures of which are hereby incorporated by reference. More recently, neurosynaptic and multiterminal chalcogenide materials and devices have been described in U.S. patent application Ser. Nos. 10/189,749; 10/384,994 and 10/426,321 to the instant assignee, the disclosures of which are hereby incorporated by reference.

In the instant deposition apparatus, chalcogenide materials may be deposited in a sputtering process to form a layer of chalcogenide material alone or in combination with one or more metal, insulating or semiconducting materials to form chalcogenide devices on a mobile discrete or continuous web substrate. Sputtering of chalcogenide materials occurs from chalcogenide sputtering targets formed by combining the desired chalcogenide and modifier elements in the appropriate stoichiometry and pressing or otherwise processing to form a target. Chalcogenide switching and memory devices having two or more terminals can be formed in a roll-to-roll fashion using the instant deposition apparatus and may be combined with conventional silicon based layers or devices and/or insulating layers and/or metal layers or metal contacts to provide devices having a chalcogenide material as the active material. Structures having chalcogenide devices in combination with polysilicon layers or devices, for example, may be formed in the instant deposition apparatus.

The foregoing drawings, discussion and descriptions are not intended to represent limitations upon the practice of the present invention, but rather are illustrative thereof. Numerous equivalents and variations of the foregoing embodiments are possible and intended to be within the scope of the instant invention. It is the following claims, including all equivalents, which define the scope of the invention.

We claim:

1. A continuous deposition apparatus comprising:
a pay-out unit, said pay-out unit providing a mobile substrate; and
a deposition unit, said deposition unit receiving said mobile substrate from said pay-out unit, said deposition unit forming a layer of a polycrystalline material on said mobile substrate, said mobile substrate being continuously transported through said deposition unit during said formation of said layer of polycrystalline material.

2. The apparatus of claim 1, wherein said mobile substrate is a continuous web substrate.

3. The apparatus of claim 1, wherein said mobile substrate is a flexible substrate.

4. The apparatus of claim 1, wherein said mobile substrate comprises a plastic.

5. The apparatus of claim 4, wherein said substrate includes a protective layer formed on said plastic.

6. The apparatus of claim 1, wherein said mobile substrate comprises steel.

7. The apparatus of claim 1, wherein said layer of polycrystalline material is formed by depositing a layer of amorphous or microcrystalline material having substantially the same composition as said layer of polycrystalline material and transforming said layer of amorphous or microcrystalline material to said layer of polycrystalline material.

8. The apparatus of claim 7, wherein said layer of amorphous or microcrystalline material is formed in a PECVD process.

9. The apparatus of claim 7, wherein said transformation step includes providing energy to said layer of amorphous or microcrystalline material.

10. The apparatus of claim 7, wherein said transformation step includes annealing said layer of amorphous or microcrystalline material.

11. The apparatus of claim 10, wherein said annealing is a rapid thermal annealing process.

12. The apparatus of claim 11, wherein said rapid thermal annealing process is completed with a xenon lamp.

13. The apparatus of claim 10, wherein said annealing is a laser annealing process.

14. The apparatus of claim 13, wherein said laser annealing process is completed with an excimer laser.

15. The apparatus of claim 7, wherein said layer of polycrystalline material is formed through an alternating sequence of said deposition and transformation steps.

16. The apparatus of claim 7, wherein said deposition unit includes a deposition chamber for depositing said layer of amorphous or microcrystalline material and said transformation step occurs in said deposition chamber.

17. The apparatus of claim 1, wherein said polycrystalline material is polysilicon.

18. The apparatus of claim 17, wherein said polysilicon is formed by depositing a layer of amorphous or microcrystalline silicon and transforming said layer of amorphous or microcrystalline silicon to polysilicon.

19. The apparatus of claim 18, wherein said layer of amorphous or microcrystalline silicon is formed from silane or disilane.

20. The apparatus of claim 1, wherein said polycrystalline material is polycrystalline SiGe.

21. The apparatus of claim 1, wherein said polycrystalline material has an average grain size of at least 100 nm.

22. The apparatus of claim 1, wherein said polycrystalline material has an average grain size of at least 500 nm.

23. The apparatus of claim 1, wherein said polycrystalline material has an average grain size of at least 1 micron.

24. The apparatus of claim 1, wherein said polycrystalline material is doped n-type or p-type.

25. The apparatus of claim 1, wherein said deposition unit includes means for sputtering or a sputtering chamber and said deposition unit further forms a layer of sputtered material on said mobile substrate.

26. The apparatus of claim 25, wherein said sputtered material is a metal or metal alloy.

27. The apparatus of claim 25, wherein said sputtered material is an oxide.

28. The apparatus of claim 1, wherein said deposition unit includes a plurality of deposition chambers, said mobile substrate being continuously transported through each of said plurality of deposition chambers, said plurality of deposition chambers forming one or more thin film layers in addition to said layer of polycrystalline material on said mobile substrate.

29. The apparatus of claim 28, wherein said one or more thin film layers includes a layer of a conducting material.

30. The apparatus of claim 28, wherein said one or more thin film layers includes a layer of an insulating material.

31. The apparatus of claim 28, wherein said one or more thin film layers includes a layer of a semiconducting material.

32. The apparatus of claim 28, wherein said one or more thin film layers includes a layer of a chalcogenide material.

33. The apparatus of claim 32, wherein said chalcogenide material comprises Se or Te.

34. The apparatus of claim 33, wherein said chalcogenide material further comprises Ge or Sb.

35. The apparatus of claim 28, wherein said deposition unit forms an nip device structure.

36. The apparatus of claim 35, wherein the intrinsic region of said nip device structure comprises said layer of polycrystalline material.

37. A thin film transistor comprising a layer of polycrystalline material, wherein said layer of polycrystalline material is formed in the apparatus of claim 1.

38. A photovoltaic device comprising a layer of polycrystalline material, wherein said layer of polycrystalline material is formed in the apparatus of claim 1.
